(19) United States
(12) Patent Application Publication
(10) Pub. No.: US 2026/0276758 A1
(43) Pub. Date: Sep. 17, 2026

(54) MAGNETIC FIELD SENSOR AND OPTICAL COLLECTOR

(71) Applicant: Elta Systems Ltd., Ashdod (IL)

(72) Inventors: Yechel BEN SHALOM, Jerusalem (IL); Nir BAR-GILL, Tel Aviv (IL); Nissan MASKIL, Herzliya (IL)

(21) Appl. No.: 19/167,575

(22) PCT Filed: Apr. 4, 2024
(86) PCT No.: PCT/IL2024/050346

§ 371 Date: Sep. 22, 2025

(30) Foreign Application Priority Data
Apr. 4, 2023 (IL) 302162

(51) Int. Cl. G01R 33/26

(52) U.S. Cl. CPC G01R 33/26

(57) ABSTRACT

An optical collector and a respective sensor unit are described. The sensor comprising at least one crystal structure comprising an ensemble of color centers, at least one optical detector and an optical collector positioned between said at least one crystal structure and said at least one optical detector for directing optical emission from said at least one crystal structure to said at least one optical detector. The least one crystal structure has geometrical shape of a trapezoid prism having one of a first and second parallel facets directed toward the optical collector. The optical collector is formed as a planar waveguide having first trapezoid section interfacing said at least one crystal and a second rectangular section for transmitting collected light toward the at least one optical detector.

### TECHNOLOGICAL FIELD

The present disclosure is in the field of collection of optical emission from a crystal structure, and specifically relates to collection of optical emission from an ensemble of color centers in crystal structure.

### BACKGROUND

Detecting RF electromagnetic radiation is essential for modern-day communication and sensing. The conventional technique uses the interaction between radiation and electrons in conductive or semiconductive materials, based on classical electromagnetism, enabling detection of strong signals. Alternatively, quantum interactions between photons and specific material properties can detect signal photon radiation and their properties.

Color centers are crystalline defects that introduce additional light absorption or emission. A common type of color center used in various quantum metrology applications utilizes a Nitrogen Vacancy (NV) defect in diamond crystals. The NV center is a nanoscale defect that can be initialized via optical pumping, readout by detection of fluorescent emission and undergo coherent manipulation using microwave (MW) fields.

The specific properties of color center in crystals, and specifically NV centers in diamond, make these centers suitable candidates for detection of electromagnetic radiation and magnetic fields in general. Further, coherent manipulation of color center state enables enhanced detection properties.

The Nitrogen-Vacancy (NV) color center in diamond is a promising system in various fields including, for example sensing and quantum metrology. The NV center is a localized atomic defect in the diamond's crystal structure with a spin degree of freedom in the electronic ground-state. The NV spin can be initialized via optical pumping using optical illumination (e.g., green or 532 nm light), read out via spin-dependent fluorescence intensity (in a red sideband between 640-800 nm), and coherently manipulated by microwave (MW) fields. These properties are useful in a broad range of applications, for example in magnetic sensing: by measuring the NV spin state, which is influenced by magnetic fields, one can extract quantitatively the magnitude and orientation of magnetic fields at the position of the NV.

Various techniques are known for collection of optical emission from NV centers or color centers in general. According to U.S. Pat. No. 10,330,744, a diamond can be used in a magnetometer to determine the strength of a magnetic field applied to the diamond. The diamond includes a first portion comprising a plurality of nitrogen vacancy (NV) centers dispersed throughout the first portion. The diamond also includes a second portion adjacent to the first portion. The second portion does not contain NV centers. The second portion is configured to facilitate transmission of light generated by the NV centers of the first portion away from the first portion.

DE 10,2018,220,027 relates to a sensor device with a crystal body (1), in particular a diamond, with a number of color centers, in particular with negatively charged nitrogen defects, a light source for irradiating the crystal body (1) with excitation light (20), and a high-frequency device for irradiating the Crystal body with microwaves, and one or more photodetectors (3) which are set up to detect fluorescent light which is generated due to the irradiation of the crystal body (1) by the light and the microwaves, the crystal body (1) having a top side (11) and having an underside (12) parallel to this, an edge of the upper side (11) being chamfered to a facet surface (15), the excitation light (20) being coupled into the crystal body (1) in this way via the facet surface (15), that it is at an angle of incidence (0) that is greater than the angle for total reflection, on the underside (12) of the crystal body (1) hits. The invention further relates to a method for producing crystal bodies (1, 1a, 1b, 1c, 1d, 1e, 1f, 1g, 1h) for such a sensor device.

WO2022091802 describes a magnetic sensor (10) that includes a diamond substrate (11) and a waveguiding body (14) that comes into contact with the diamond substrate (11). The diamond substrate (11) comprises, on a surface (11a) with which the waveguiding body (14) does not come into contact, a first layer (11La) including a diamond crystal with an NV center (12) positioned therein, and on a surface (11b) with which the waveguiding body (14) comes into contact, a second layer (11Lb) on which a conductor pattern (13) is positioned. The waveguiding body (14) comprises a wire path (15) that transmits microwaves to the conductor pattern (13), said microwaves producing electron spin resonance, and an optical waveguide path (16) that transmits an excitation light and fluorescence, said excitation light irradiating the diamond substrate (11), and said fluorescence being produced by the excitation light in the first layer (11La) of the diamond substrate (11).

US2017343620 describes systems and methods using a magneto-optical defect center material magnetic sensor system that uses fluorescence intensity to distinguish the mₛ=±1 states, and to measure the magnetic field based on the energy difference between the mₛ=+1 state and the mₛ=−1 state, as manifested by the RF frequencies corresponding to each state in some embodiments. The system may include an optical excitation source, which directs optical excitation to the material. The system may further include an RF excitation source, which provides RF radiation to the material. Light from the material may be directed through a light pipe to an optical detector. Light from the material may be directed through an optical filter to an optical detector.

### GENERAL DESCRIPTION

Color centers, and specifically nitrogen vacancy centers in crystals can provide sensitive and efficient sensing allowing single photon sensitivity. There is a need in the art for a technique and optical arrangement providing efficient collection of light emitted by one or more color centers. Efficient collection and detection of the emitted light enables to maintain high sensitivity of the sensor.

Generally, as the basic noise source in sensors based on color centers, and specifically in NV sensors, is the shot noise of the fluorescence, sensor sensitivity is proportional to the square root of the collected power. This indicates that efficiency in collection of fluorescence emission from the color centers may greatly enhance sensor sensitivity. There are various solutions aimed at increasing the collection efficiency from NV diamonds. One common solution utilizes a Compound Parabolic Collector (CPC) that may collect about 20% of the emitted light or more. Some main issues with the currently used collection technique relate to complicated arrangement and the large space needed around the diamond for the light collection arrangement. More specifically, CPC collectors are relatively large and bulky and are limited when used in sensor arrays. Additionally, the manufacturing of CPC collectors is complicated and expensive relative to the configuration described hereinbelow.

The present disclosure provides an optical collector for collection of fluorescence emission from an ensemble of color centers. The optical collector is formed of a planar waveguide having first trapezoid section at a first end adapted to interface one or more crystals, and a second rectangular section extending from the first end toward a second end providing output of collection light.

The collector is generally adapted for collecting fluorescent emission from a crystal structure carrying an ensemble of color centers. Thus, allowing to enhance sensitivity of a sensor unit based on such crystal structure.

Further, according to some embodiments of the present disclosure, the crystal structure is cut is selected geometric shape to enhance emission of fluorescent light is a selected direction, utilizing total internal reflection properties to direct fluorescent emission to exit the crystal structure at a selected face, where an optical collector may be placed to directed the collected light toward a detector. More specifically, the crystal structure may be pre-cut in a trapezoid shape having first and second parallel facets, while other facets are inclined to form the three-dimensional trapezoid structure.

Thus, according to a broad aspect, the present disclosure provides a sensor unit comprising at least one crystal structure comprising an ensemble of color centers, at least one optical detector and an optical collector positioned between said at least one crystal structure and said at least one optical detector for directing optical emission from said at least one crystal structure to said at least one optical detector;
wherein said at least one crystal structure has geometrical shape of a trapezoid prism having one of a first and second parallel facets directed toward the optical collector; and
wherein said optical collector is formed as a planar waveguide having first trapezoid section interfacing said at least one crystal and a second rectangular section for transmitting collected light toward the at least one optical detector.

According to some embodiments, the at least one crystal structure is placed to face said optical collector along a large one of said first and second parallel facets.

According to some embodiments, at least one of the crystal structure comprises reflective coating on at least one face.

According to some embodiments, the crystal structure comprises reflective coating on two or more faces thereof, and wherein at least faces are not coated by reflective coting to allow emitted light transmission toward said optical collector and to allow input excitation light impinging onto said crystal structure.

According to some embodiments, the at least one crystal is a diamond crystal.

According to some embodiments, the ensemble of color centers comprise one or more Nitrogen Vacancy centers. According to some embodiments, the ensemble of color centers is an ensemble of Nitrogen Vacancy centers.

According to some embodiments, the optical collector is formed of a single unit waveguide. In some other embodiments, the optical collector may be formed of two sections having first and second different refractive indices.

According to some embodiments, the optical collector is formed of glass having refractive index between 1.4 and 2.2 for wavelengths in a range between 620 and 800 nanometer.

According to some embodiments, the optical collector is flexible along at least the second rectangular section thereof.

According to some embodiments, the sensor unit may further comprise at least one microwave resonator positioned for applying selected magnetic field onto said at least one crystal structure.

According to some embodiments, the sensor unit may further comprise at least one laser unit and optical arrangement adapted to provide selective optical excitation of said at least one crystal structure.

According to some embodiments, the sensor unit may further comprise a magnetic field generator adapted to provide static magnetic field onto said at least one crystal structure. According to some embodiments, the magnetic field generator may be a statis magnetic field generator. According to some embodiments, the magnetic field generator may be adapted to selectively vary magnitude of said static magnetic field.

According to one other broad aspect, the present disclosure provides a sensor array system comprising an array of sensor units comprising at least one sensor unit configured as described herein. The at least one sensor unit may comprise at least one crystal structure comprising an ensemble of color centers, at least one optical detector and an optical collector positioned between said at least one crystal structure and said at least one optical detector for directing optical emission from said at least one crystal structure to said at least one optical detector;
wherein said at least one crystal structure has geometrical shape of a trapezoid prism having one of a first and second parallel facets directed toward the optical collector; and
wherein said optical collector is formed as a planar waveguide having first trapezoid section interfacing said at least one crystal and a second rectangular section for transmitting collected light toward the at least one optical detector.

According to yet another broad aspect, the present disclosure provides a sensor array system comprising an array of sensor units, each sensor unit being configured as described herein.

According to yet a further broad aspect, the present disclosure provides an optical collector comprising a waveguide unit having a first length dimension, a second width dimension and a third height dimension, wherein said first length dimension is longer than said second width dimension, and said second width dimension is wider than said third height dimension, and wherein said waveguide unit having a trapezoid prism form at one end thereof defining a first facet having an aera smaller than area formed by said second width dimension and said third height dimensions, and wherein said first facet being configured as input facet of the waveguide unit.

According to some embodiments, the optical collector may be configured for collecting optical emission from at least one crystal having one or more color centers.

According to some embodiments, the optical collector may be configured for collecting optical emission from at least one diamond having one of more NV centers.

According to some embodiments, the at least one diamond has a trapezoid prism shape.

According to yet another broad aspect, the present disclosure provides an optical collector comprising a first section having trapezoid projection and a second section having a rectangular projection, an input port located at a smaller facet of the first trapezoid section and an output port located at a facet of said second rectangular section.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 schematically illustrates a sensor unit according to some embodiments of the present disclosure;

FIGS. 2A and 2B exemplifies a trapezoid (FIG. 2A) and truncated pyramid (FIG. 2B) structures according to some embodiments of the present disclosure;

FIGS. 3A to 3C exemplify configuration of an optical collector according to some embodiments of the present disclosure, FIG. 3A is a schematic illustration exemplifying structure angles, FIG. 3B exemplifies three-dimensional configuration, and FIG. 3C is an image of optical collector use in some experiments;

FIG. 4 shows an image of a crystal structure cut into trapezoid shape according to some embodiments of the present disclosure; and

FIG. 5 illustrates schematically a sensor system according to some embodiments of the present disclosure.

### DETAILED DESCRIPTION OF EMBODIMENTS

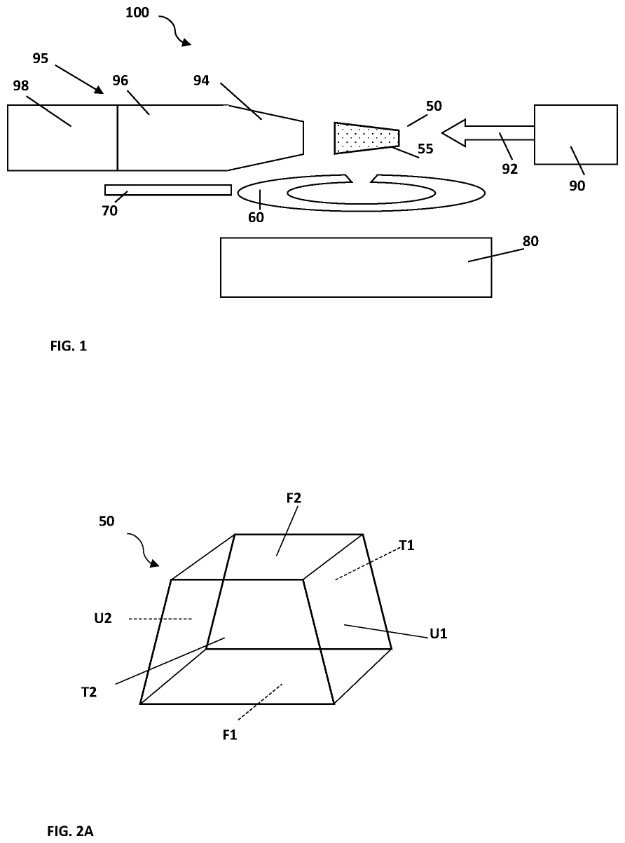

As indicted above, the present disclosure provides a sensor unit and an optical collector configured for enhancing light collected from one or more color centers within a crystal structure. Reference is made to FIG. 1 exemplifying a sensor unit 100 according to some embodiments of the present disclosure. The sensor unit 100 utilizes a crystal structure 50 having one or more of color centers 55 embedded therein (generally an ensemble of color centers). The one or more color centers 55 in the crystal structure act as isolated quantum systems that can be manipulated by proper excitations and provide fluorescent emission in response to collected radiation of selected frequency. Sensor unit 100 also includes an optical collector 95, positioned to collect fluorescent emission from the color centers 55 of crystal structure 50 and direct the collected light toward a detection unit 98 that includes one or more detectors.

The sensor unit may also include a resonator circuit 60 such as microwave resonator, a static magnetic field generator 80, and a light source unit 90 (e.g., laser light source). These additional units provide selected fields for controlling and modifying excitation of the ensemble of color centers 55. The resonator may be associated with electrical lead/connections 70 for directing electrical signals to the resonator 60.

The resonator circuit 60 may be formed of one or more resonators, generally aligned to resonance frequency of the color centers 55. The resonator circuit enables applying a magnetic field of selected amplitude and phase onto the one or more color centers 55.

The static magnetic field generator 80 may be a permanent magnet, electromagnet or other devices configured to provide a generally statis magnetic field applied on the crystal structure 50 and the ensemble of color centers 55 embedded therein. Static magnetic field may be used to tune separation between spin states of the color centers.

A light source 90 may be used to provide optical illumination 92 for optically pumping the color centers. This may be sued for providing selected excited state of the color centers as known in the art for operating color centers such as NV centers in diamond crystals for detection of magnetic field or electromagnetic radiation.

To enhance collection of optical emission from the one or more color center 55 of crystal structure 50, The crystal structure according to the present disclosure is generally provided, or pre-cut, with a selected trapezoid prism geometrical shape. More specifically, the crystal structure is shaped to have first and second facets parallel between them, and at least two facets connecting the first and second parallel facets at a certain angle other than 90°. The crystal structure may include two additional facets, which may be parallel forming a crystal configuration having trapezoid projection in one orientation and rectangular projection in another orientation. In some configurations, the crystal structure 50 is formed with two parallel facets, and at least two pairs of facets connecting the parallel facets in angular orientation other than 900 thereby forming trapezoid projection in more than one orientation. The crystal structure 50 is positioned such that a larger one of the first and second parallel facets faces the optical collected 95.

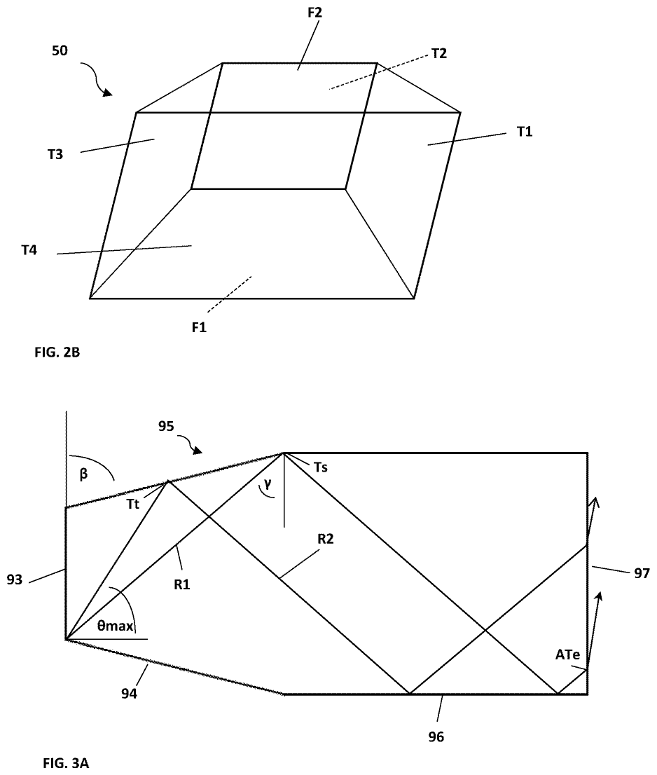

More specifically, in some embodiments the crystal structure 50 may be formed by a three-dimensional geometric shape that is formed by two parallel trapezoids T1 and T2, connected by rectangular faces F1, F2, U1 and U2, illustrated in FIG. 2A. The parallel trapezoids have two pairs of sides that are parallel to each other, forming base of the first F1 and second F2 parallel facets and trapezoid sides T1 and T2. The parallel sides are not equal in length, giving them a non-uniform shape and defining a larger one of the first and second parallel facets. The rectangular faces U1 and U2 connecting the parallel trapezoids are perpendicular to the bases and have equal length. The height of the prism is the distance between the parallel trapezoids. The overall structure of the trapezoid prism is similar to that of a regular rectangular prism, but with non-uniform trapezoidal bases instead of squares or rectangles. For simplicity, dashed lines relate to the back facets of the geometrical structure in the figure.

In some other embodiments, the crystal structure 50 may be formed as a truncated pyramid, or a frustum, as illustrated in FIG. 2B. The crystal structure 50 is formed by a shape that has first F1 and second F2 parallel facets that are square rectangular or trapezoids, having first and second surface area, different between them. The first F1 and second F2 parallel facets are connected by rectangular, parallelogram, or trapezoid sides T1-T4. The sides T1-T4 of the truncated pyramid are generally not parallel to each other. The height of the truncated pyramid is the perpendicular distance between the first and second parallel facets. The overall structure of the truncated pyramid is similar to that of a regular pyramid, but with the top portion removed.

The geometrical configuration of the crystal structure 50 is directed at utilizing total internal reflection to direct light emitted by fluorescence from the one or more color centers embedded therein, to direct the light to exit the crystal structure through one or the first and second parallel facets.

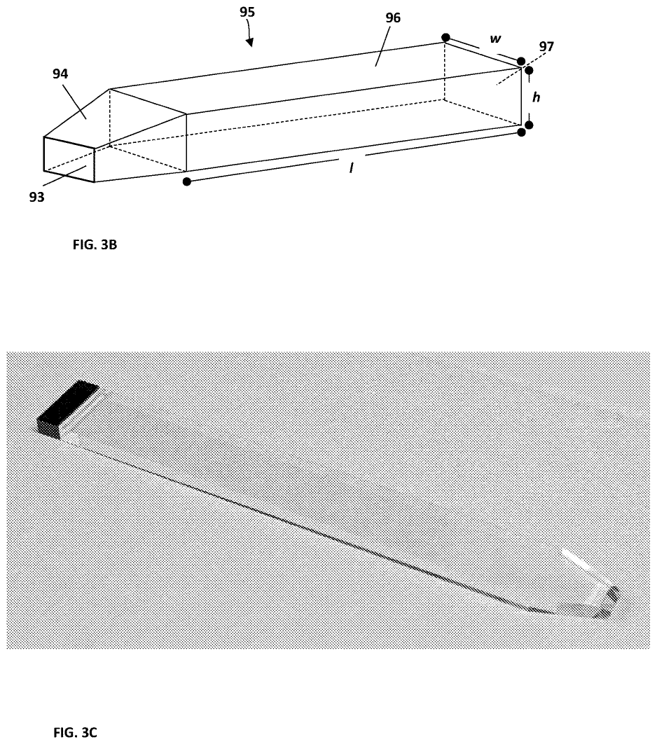

To collect light emitted from the crystal structure, sensor unit 100 may utilize an optical collector 95. The optical collector is formed as a waveguide for directing light emitted from the crystal structure 50 toward a detector unit 98. Exemplary configurations of the optical collector 95 are illustrated in FIGS. 3A to 3C. FIG. 3A exemplifies a two-dimensional representation of the optical collector, FIG. 3B exemplifies a three-dimensional configuration of the optical collector, and FIG. 3C is an image of optical collectors used to provide experimental data as described further below. As shown, the optical collector is formed as a planar waveguide having first trapezoid (or truncated pyramid) section 94 interfacing said at least one crystal and a second rectangular section 96 for transmitting collected light toward the at least one optical detector.

FIG. 3A illustrates a compound trapezoid collector 95 according to some embodiments of the present disclosure. The collector 95 includes a first portion 94 having an input facet 93, which is generally positioned to face a facet of the crystal structure, and a second portion 96 directing light toward an output facet 97. FIG. 3A also illustrates light rays R1 and R2 collected at corner of input facet 93 and transmitted by total internal reflection through the collector toward output facet 97. The output facet 97 is generally directed and/or oriented to face a detector unit 98 for collecting emitted photons and generating electrical signals indicative thereon.

FIG. 3B is a three-dimensional illustration of optical collector 95. As shown, the optical collecting includes a first portion 94 configured to face the crystal structure 50 for collecting light emitted from the crystal structure through input facet 93, and a second portion 96 extending from the first portion 94. The second portion 96 is of a selected length l providing light guiding from the crystal structure 50 of the sensor unit 100, toward a detection unit 98, which may be located at a selected distance from the crystal structure 50.

In this connection, the first portion 94 may be in the form of a trapezoid prism as defined above. Alternatively, the first portion 94 may be in the form of a truncated pyramid as defined above. In some embodiments, the bottom surface of the first portion 94 may be aligned as continuation of bottom surface of the second portion, to simplify alignment and placement of the optical collector. In some embodiments, the transition between the first and second portion may be a well-defined transition line as illustrated in FIGS. 3A and 3B. In some embodiments, the transition between the first and second portions may be gradual, providing a generally smooth gradient.

Additionally, the second portion 96 may have a selected ratio between width w and height h of the second portion, defining a generally wide and low waveguide. The second portion 96 may be rigid in accordance with material use for forming the optical collector. In some embodiments, the second portion 96 may be flexible with respect to curves around height thereof, enabling certain flexibility in guiding the collected optical signals toward the detector unit 98.

FIG. 3C shows an image of an optical collector fabricated for experimental study by the inventors. The optical collector in this example was formed of CDGM QF14 and includes a 3 mm color filter at output facet thereof, shown by dark end of the collector in FIG. 3C.

The basic noise source of sensors utilizing color center, and specifically NV-based sensors, relates to shot noise of the fluorescence emission. The sensitivity for fluorescence detection is generally proportional to the square root of the collected power. There are various solutions aimed at increasing the collection efficiency from diamonds, however these solutions are typically complicated and bulky requiring large space around the diamond. The technique described herein enables enhancing collection efficiency, while maintaining the possibility to operate with a small form factor, allowing arrangement of a plurality of sensors within an array, or maintaining the small space required for a sensor utilizing color centers such as nitrogen vacancy (NV).

Typically, due to the total internal reflection, much of the emitted light may be trapped inside the crystal structure. For cuboid crystal structure, the trapped light may be 70% or more. Attaching selected material to one or more faces of the crystal structure can force part of the light to emit into the material, and the fraction of released light depends on refractive index of the selected material. For example: standard glass with n=1.5 provides collection of 17% of the emission, and flint glass with n=1.8 provides collection of 29% of emitted light.

Several techniques enable increasing the amount of light released from the crystal structure. One technique provided by some embodiments of the present disclosure utilizes breaking the cuboid symmetry of the crystal structure and using a crystal structure cut to a selected shape. An alternative technique includes a crystal structure coated with reflected layer on facets other than those directed at a collector or detector. Following extraction of light from the crystal structure, an optical collector may be used for guiding the collected light to a detection unit and one or more photodetectors. Generally, the emission after refraction is spread in half-sphere solid angle, however, the angular distribution may be non-uniform and may follow probability density function such as:

$$\hat{θ} ∝ \frac{sin θcosθ}{\sqrt{1 - {( {n}_{out} / {n}_{in} )}^{2} {sin}^{2} θ}} \cdot \frac{1}{2} [ {T}_{S} ( θ ) + {T}_{R} ( θ ) ] \qquad ( equation 1 )$$

Here while \hat{θ} is a random variable relating to an angle between a direction of propagation of emitted photon and the normal to the surface from which the photons are released from the crystal structure, nᵢₙ and nₒᵤₜ are the refractive indices of the crystal structure and the collector respectively, and T_{S}(θ) and T_{R}(θ) are Fresnel transmission coefficients. This relation indicates that emission directed at large angles, e.g., above 70°, is relatively low, and may be below 10%.

For simplicity, the part of the emission that is transmitted from the crystal structure into the optical collected is referred to as emission efficiency ηc1, and the part of the light transmitted by the collector toward output facet thereof is referred to as guidance efficiency ηc2. Accordingly, the total collection efficiency is estimated by: fc=ηc1·ηc2.

To achieve high guidance efficiency ηc2, the present disclosure provides an optical collector formed as a planar waveguide having first trapezoid section interfacing said at least one crystal structure and a second rectangular section guiding the collected light toward a detection unit. The optical collector is referred to herein as Compound Trapezoid Collector (CTC). The concept is of a cuboid collector with a pyramid shape on the input side. Dimensions of the optical collector are generally selected in accordance with conditions for total internal reflection at selected extreme conditions within the optical collector including for example: total reflection from the tangent marked by Tt in FIG. 3A, total reflection from the side marked by Ts in FIG. 3A and avoiding total reflection at output facet marked by Ate in FIG. 3A.

Generally, an optical collector designed to provide conditions for total internal reflection tangent rays (Tt) and at the sides of the second portion (Ts), as well as avoiding total internal reflection at output facet (Ate), may result in large dimensions and reduced etendue. The dimensions of the CTC may be selected based on defined conditions associated with light propagation through the optical collector, and specifically some extreme rays illustrated by Tt, Ts and Ate in FIG. 3A.

The relevant conditions may be defined by angles β, θₘₐₓ, and γ shown in FIG. 3A by:

$$β < 180 - θmax - α c 1$$

$$γ > α c 1$$

$$γ > 90 - α c 2$$

where β is the angle of the tangent of the first, trapezoid, section, γ is the maximum angle of reflected ray arriving at the internal surface of the first portion, αc1 is the critical angle from the collector to its clad, and αc2 is the critical angle from the collector to the next material. Generally, γ can be expressed as function of the collector dimensions, where r is half the collection are of the input facet 93, and R is half the output are of output facet 97:

$$γ = {tan}^{- 1} ( \frac{R - r}{R + r} \cdot \frac{1}{cos β} ) \qquad ( equation 2 )$$

In some examples, β may be selected to be β=180−θₘₐₓ−αc1, i.e., smaller possible β.

Accordingly, selection of optical collector dimensions that give up on collection of light components emitted at large angles can reduce the dimensions, and as indicated above with reference to equation 1, result in a weak effect on the efficiency. Accordingly, the optical collector may be designed for efficient light collection up to emission angle θₘₐₓ can be described by two conditions:

$$\frac{R - r}{R + r} \cdot \frac{1}{cos β} \geq tan α \qquad ( equation 3 )$$

$$R \geq r \cdot \frac{1 + cos βtanα}{1 - cos βtanα}$$

where α=max{α_{c1},90−α_{c2}}, and β=180°−θₘₐₓ−α_{c1}. Thus, for a given material and input facet dimensions, a maximal collection angle θₘₐₓ can be selected to maintain conditions allowing output of collected light at the output facet.

Efficiency of extraction and collection of emitted light from the crystal structure was tested by simulation and experiments. The simulations include study of three methods on the light collection efficiency: using high refractive index material of the optical collector, the use of a crystal structure (e.g., diamond) cut in a trapezoid shape, and coating surfaces of the crystal structure. The designs were performed in SOLIDWORKS and RayVis and imported into TracePro for ray-tracing simulations. The emission source is designed as small radiate spheres located inside the crystal structure, and the detector (photodiode) was simulated by a perfect absorbing surface with similar dimensions to a selected detector unit (Thorlabs DET100A2 Ø9.8 mm).

The simulations were performed using several scenarios including: glass optical collector and cuboid diamond; flint glass optical collector and a cuboid diamond; flint glass optical collector and a trapezoid diamond, where and angles are chosen to be 10°; flint glass optical collector and a trapezoid diamond with reflective coating, where all the faces are simulated as a perfect mirror except the output surface directed at the optical collector and the bottom surface allowing input illumination (92 in FIG. 1).

The materials selected for simulations are SCHOTT BK7 (nᵣ=1.51) for glass, and SCHOTT SF56 (nᵣ=1.77) for flint glass, where the crystal structure simulated is diamond. The optical collector was designed as a pyramid with reflected sides, and the exit surface is a perfectly absorbing surface. This method allows measurement of all the emission that passes into the collector. The simulation result indicated efficiencies of 18.3% for glass optical collector and cuboid diamond; 28% for flint glass optical collector and a cuboid diamond; 64.2% for flint glass optical collector and a trapezoid diamond; and 80.3% for flint glass optical collector and a trapezoid diamond and reflective coating.

Additional simulation was conducted on selected configurations of the optical collector. This simulation used a trapezoid diamond and use was directed at two types of optical collectors: Compound Parabolic Collector (CPC) as a body of revolution, and Compound Trapezoid collector (CTC) having a rectangular cross-section. The exit surface of the diamond was chosen to be 3×0.5 mm² and the detector dimension was chosen to be a circle with 9.8 mm diameter. A 3 mm thick filter was placed between the optical collector and the detector, having selected refractive index such as BK7 (1.51 at 632.8 nm). The input facet of the optical collector was selected to be larger than the diamond output facet, and the output facet was a circular facet having circumference of 9.3 mm.

A comparison of the CPC and CTC performance for the two types of glass is shown in table 1.

TABLE 1

| Type | Dᵢₙ | Dₒᵤₜ | Length | Efficiency (%) |
|---|---|---|---|---|
| CPC - Glass | 3.1 | 9.3 | 17.5 | 98.1 |
| CPC - flint | 3.1 | 9.3 | 17.5 | 97.3 |
| CTC - glass | 3/0.5 | 8.9/2 | >6 | 90.1 |
| CTC - flint | 3/0.5 | 8.9/2 | >6 | 81.3 |

This simulation indicates that the CTC performance is almost similar to that of the CPC. However, the CTC configuration is advantageous in terms of space cost, providing smaller form factor. Additionally, the CTC configuration of the optical collector is advantageous in terms of manufacturing complexity and cost.

It should be mentioned that the small effect on the CTC efficiency may be associated with reflection from the exit surface. This is since the reflection at the output facet is higher in large angles, even above the critical angle. Accordingly, in some embodiments, the collected may be formed of at least first and second materials having first and second refractive indices. More specifically, a first section of the optical collector may be formed of a first material having a first (higher) refractive index, and a second section of the optical collector may be formed of a second material having a second (lower) refractive index. The first and second materials may interface at the interface between the first trapezoid section and the second rectangular section of the optical collector. For example, the first refractive index may be between 1.6 and 2.0 (e.g., 1.8), and the second refractive index may be between 1.4 and 1.7 (e.g., 1.5 or 1.59). This configuration provides a double step optical collector. In some embodiments, the use of double steps collectors or coupling the detector to the exit surface may enable increase the efficiency to almost 100%.

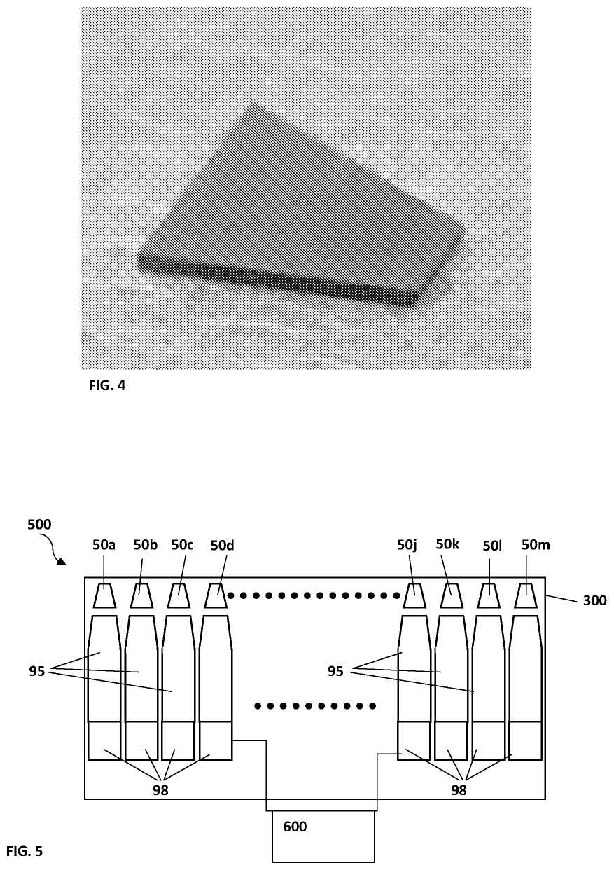

An experimental study used HPHT diamond pre-cut it into a trapezoid shape in both dimensions. FIG. 4 shows an image of the cut diamond. The diamond was cut at angles of 10°, and based on the simulation data, the effect of specific angles on the efficiency is relatively weak. The optical collector shown in FIG. 3C was a CTC formed of CDGM QF14 (by Optec Ltd) having a refractive index of 1.59. The optical collector was formed with dimensions were 3×0.6 mm² input facet, 9×2 mm² output facet and length of 70 mm. A cuboid long pass filter (SCHOTT RG665 dim 9×2×3 mm³) was placed at the output facet using UV-curing glue (Thorlabs NOA61).

The collection efficiency of the collector, of this configuration was compared to collection using lenses from the front of the diamond, which provides low but easy to estimate efficiency. In the lens collection technique, a 030 mm window was placed at a fixed position of 61 mm from the diamond, in order to get well-defined collection angles. Measuring of the voltage on both collection paths and comparing indicates 33% collection efficiency of the optical collector according the to present technique. Simulation of this collector, including the material, low refractive index immersion oil, and unnecessary chamfer, shows 40% collection efficiency. Accordingly, the technique of the present disclosure indicates enhanced collection efficiency, while allowing small form factor of and optional flexibility the optical collector.

The efficiency was compared to a given window of diameter D and distance d, providing an angle to the normal:

$${θ}_{out} = {tan}^{- 1} ( \frac{D}{2 d} )$$

According to Snell low, and angle into the diamond is:

$${θ}_{in} = {sin}^{- 1} ( \frac{{n}_{air}}{{n}_{diamond}} sin ( {θ}_{out} ) ) = 5.7 °$$

And the solid angle of all the angles bellow theta:

$${Ω}_{c} = {\int }_{0}^{{θ}_{in}} {\int }_{0}^{2 π} sin θ d ϕ d θ = 2 π ( 1 - cos {θ}_{in} )$$

The collection efficiency is this angle divide by the full sphere:

$${η}_{c} = \frac{{Ω}_{c}}{4 π} = \frac{1}{2} ( 1 - cos {θ}_{in} )$$

In some examples D=30 mm, d=61 mm providing η_{c}=0.25%. Exciting the diamond is excited by laser and measuring the voltage of the collection paths indicates a ratio of 132, which means 33% collection efficiency of the optical collector as defined herein above.

Accordingly, the present disclosure provides a sensor unit utilizing at least one crystal structure having one or more color centers, and optical collector for efficient collection of light emitted from the crystal structure.

Further to the above-described configuration, simulation and experimental data, the sensor unit 100 configuration according to various embodiments of the present disclosure may be used as a single sensor arrangement, or in a sensor system including an arrangement of a plurality of sensor units. FIG. 5 illustrates a sensor system 500 including an array 300 of sensor units. The sensor system 500 may also include a controller 600 configured for collecting output data from the plurality of sensor units and process, store and/or transmit the detection data. The sensor units generally include respective crystal structures 50a, 50b, to 50m arranged in a selected arrangement. Each of the crystal structure include color centers embedded within, e.g., diamond crystals having a plurality of NV centers in each diamond. The crystal structures include at least one crystal structure having a trapezoid shape or truncated pyramid shape as described above. Further, at least one of the crystal structure is associated with a respective optical collector 95 having a first trapezoid (or truncated pyramid) shaped section, and a second rectangular section. The optical collector 95 is positioned facing a larger surface of two parallel surfaces of the crystal structure, to collect light emitted from the color centers, and faces a detector unit 98 at other end of the second portion for directing the collected light to the detector unit 98. It should be noted that the illustration of FIG. 5 is not to scale, sizes of objects and spaces or gaps between the elements of the system are shown for illustration and do not directly reflect dimensions of the system.

In some embodiments, the plurality of crystal structures 50a to 50m are configured with selected trapezoid or truncated pyramid shape, and the respective optical collectors 95 are configured with a first trapezoid portion and second rectangular portion as described above.

The array of sensors 300 may have any selected arrangement and geometry. For example, the array of sensors 300 may be a one-dimensional or two-dimensional array. The array 300 may be operated for detection of spatial variations in electromagnetic radiation, e.g., using phased array techniques, and may include a readout circuit for collecting detection data from the plurality of sensor units.

Generally, although not shown in FIG. 5, each of the crystal structures is associated with a resonator circuit for applying magnetic field of selected frequency and exciting the color centers. Additionally, the crystal structures are associated with respective light source units, such as one or more laser units, for providing pumping illuminations. Furthermore, the crystal structures may be places in selected statis magnetic field conditions, generated by a magnetic field generator for tunning separation between quantum states of the color centers.

Thus, the present disclosure provides a sensor unit and an optical collector configured to enhance collection of fluorescence emission from one or more color centers used by the sensor unit. The sensor unit utilizes at least one crystal structure having color centers embedded therein. The crystal structure is configured with a trapezoid of truncated pyramid shape for enhancing outcoupling of light and reducing conditions for total internal reflection for the emitted light. The optical collector may be formed from a selected material, generally transmitting light of the fluorescence wavelength range, and having refractive index greater than the surrounding thereof, to thereby guide the emitted light toward a respective detector unit.

It is to be noted that the various features described in the various embodiments can be combined according to all possible technical combinations.

It is to be understood that the invention is not limited in its application to the details set forth in the description contained herein or illustrated in the drawings. The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based can readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

1. A sensor unit, comprising:
at least one crystal structure comprising an ensemble of color centers;
at least one optical detector; and
an optical collector positioned between said at least one crystal structure and said at least one optical detector for directing optical emission from said at least one crystal structure to said at least one optical detector;
wherein said at least one crystal structure has geometrical shape of a trapezoid prism having one of a first and second parallel facets directed toward the optical collector; and
wherein said optical collector is formed as a planar waveguide having first trapezoid section interfacing said at least one crystal structure and a second rectangular section for transmitting collected light toward the at least one optical detector.

2. The sensor unit of claim 1, wherein said at least one crystal structure is facing said optical collector along a large one of said first and second parallel facets.

3. The sensor unit of claim 1, wherein said at least one crystal structure comprises reflective coating on at least one face.

4. The sensor unit of claim 3, wherein said at least one crystal structure comprises reflective coating on two or more faces thereof, and wherein at least faces are not coated by reflective coting to allow emitted light transmission toward said optical collector and to allow input excitation light impinging onto said crystal structure.

5. The sensor unit of claim 1, wherein said at least one crystal structure is a diamond crystal.

6. The sensor unit of claim 1, wherein said ensemble of color centers comprise one or more Nitrogen Vacancy centers.

7. The sensor unit of claim 1, wherein said ensemble of color centers is an ensemble of Nitrogen Vacancy centers.

8. The sensor unit of claim 1, wherein said optical collector is formed of a single unit waveguide.

9. The sensor unit of claim 1, wherein said optical collector is formed of glass having refractive index between 1.4 and 2.2 for wavelengths in a range between 620 and 800 nanometer.

10. The sensor unit of claim 1, wherein said optical collector is flexible along at least second rectangular section thereof.

11. The sensor unit of claim 1, further comprising at least one microwave resonator positioned for applying selected magnetic field onto said at least one crystal structure.

12. The sensor unit of claim 1, further comprising at least one laser unit and an optical arrangement adapted to provide selective optical excitation of said at least one crystal structure.

13. The sensor unit of claim 1, further comprising a magnetic field generator adapted to provide static magnetic field onto said at least one crystal structure.

14. The sensor unit of claim 13, wherein said magnetic field generator is adapted to selectively vary magnitude of said static magnetic field.

15. A sensor array system comprising an array of sensor units comprising at least one sensor unit configured according to claim 1.

16. A sensor array system, comprising:
an array of sensor units, each of the array of sensor comprising:
at least one crystal structure comprising an ensemble of color centers;
at least one optical detector; and
an optical collector positioned between said at least one crystal structure and said at least one optical detector for directing optical emission from said at least one crystal structure to said at least one optical detector;
wherein said at least one crystal structure has geometrical shape of a trapezoid prism having one of a first and second parallel facets directed toward the optical collector; and
wherein said optical collector is formed as a planar waveguide having first trapezoid section interfacing said at least one crystal and a second rectangular section for transmitting collected light toward the at least one optical detector.

17. An optical collector, comprising:
a waveguide unit having a first length dimension, a second width dimension and a third height dimension,
wherein said first length dimension is longer than said second width dimension, and said second width dimension is wider than said third height dimension, and
wherein said waveguide unit having a trapezoid prism form at one end thereof defining a first facet having an aera smaller than area formed by said second width dimension and said third height dimensions, and
wherein said first facet being configured as input facet of the waveguide unit.

18. The optical collector of claim 17, configured for collecting optical emission from at least one crystal having one or more color centers.

19. The optical collector of claim 17, configured for collecting optical emission from at least one diamond having one of more NV centers.

20. The optical collector of claim 19, wherein said at least one diamond having a trapezoid prism shape.

21. (canceled)
